(19) United States
(12) Patent Application Publication
(10) Pub. No.: US 2014/0109824 A1
(43) Pub. Date: Apr. 24, 2014

(54) METHOD OF GROWING SILICON SINGLE CRYSTAL

(71) Applicants: Jung Ha Hwang, Gumi-city (KR); Sang Hee Kim, Gumi-city (KR)

(72) Inventors: Jung Ha Hwang, Gumi-city (KR); Sang Hee Kim, Gumi-city (KR)

(21) Appl. No.: 13/823,932

(22) PCT Filed: Nov. 16, 2012
(86) PCT No.: PCT/KR2012/009746

§ 371 Date: Mar. 15, 2013

(30) Foreign Application Priority Data
Jan. 5, 2012 (KR) 10-2012-0001581

(51) Int. Cl. C30B 15/04; C30B 15/22

(52) U.S. Cl. CPC C30B 15/04; C30B 15/22
USPC 117/21

(57) ABSTRACT

Disclosed is a method of growing a silicon single crystal. The method includes preparing a silicon melt, adding a dopant having a lower melting point than the silicon melt to the silicon melt, and growing a silicon single crystal from the silicon melt to which the dopant is added in the order of a neck, a shoulder, and a body. During the silicon single crystal growth, the length of a neck is adjusted in the range of 35 to 45 cm, and a ratio of inert gas quantity to pressure of a chamber is adjusted to 1.5 or less.

### TECHNICAL FIELD

The present invention relates to a method of growing a silicon single crystal.

### BACKGROUND ART

In general, in a Czochralski process of growing a silicon single crystal having a concentration greater than a predetermined level using a low-melting point N-type dopant such as antimony (Sb), phosphorus (P), and arsenic (As), the dopant added to a silicon melt volatilizes, resulting in continuous dopant loss.

In this regard, the surface temperature of the silicon melt is continuously reduced during volatilization, so that the surface temperature of the silicon melt cannot be stably maintained.

In addition, an increase in the amount of the low-melting point dopant to improve electron mobility may exponentially increase the amount of the dopant volatilizing for a predetermined time.

Meanwhile, it has been known that a convex solid-liquid interface effectively improves crystal growth rate and reduces crystal defects, compared to a concave solid-liquid interface while growing the silicon single crystal.

Thus, as growth rate increases, the solid-liquid interface has a convex shape, and heat of solidification is mostly removed through thermal conduction via the silicon single crystal.

On the other hand, as the growth rate decreases, the solid-liquid interface has a concave shape. In this case, latent heat of solidification reduces a supercooled region to decrease temperature gradient for silicon single crystal growth, thereby decreasing the growth rate of the crystal.

Accordingly, during the growth of the silicon single crystal, as the solid-liquid interface becomes more convex, there is less transfer of latent heat of solidification into the supercooled region formed under the solid-liquid interface.

Based on these grounds, the above-described concept has been applied to related fields in order to increase yield or improve productivity of the silicon single crystal.

However, when the silicon single crystal is grown by adding a low-melting point dopant thereto, Marangoni tension decreases due to heat of vaporization caused by volatilization of the highly volatile dopant. Thus, a supercooled region may be reduced.

Furthermore, in order to supply the silicon melt with a concentration greater than a predetermined level into the silicon single crystal, constitutional supercooling is required. However, constitutional supercooling produces an inverse temperature gradient that inhibits normal silicon single crystal growth.

Thus, since solidification occurs at a lower position than a normal solidification position, it is difficult to grow a silicon single crystal and productivity considerably decreases according to conventional techniques.

### DISCLOSURE

### Technical Problem

An object of the present invention devised to solve the problem lies in a method of growing a silicon single crystal capable of increasing silicon single crystal yield and improving productivity in growth of a high purity silicon single crystal using a low-melting point dopant.

### Technical Solution

The object of the present invention can be achieved by providing a method of growing a silicon single crystal including preparing a silicon melt; adding a dopant having a lower melting point than the silicon melt to the silicon melt; and growing a silicon single crystal from the silicon melt to which the dopant is added in the order of a neck, a shoulder, and a body. In this regard, a length of the neck is adjusted to 35 to 45 cm, and a ratio of inert gas quantity to pressure of a chamber is adjusted to 1.5 or less in the growing of the silicon single crystal.

The adjusting of the ratio of inert gas quantity to pressure of a chamber may be applied to from growth of the shoulder in the growing of the silicon single crystal.

A rotation rate of the silicon single crystal is in the range of 12 to 16 rpm in the growing of the silicon single crystal or a rotation rate of a crucible containing the silicon melt is in the range of 12 to 16 rpm in the growing of the silicon single crystal.

A solid-liquid interface of the silicon single crystal may be controlled to have a step difference of 20% or less between the center of the solid-liquid interface and an edge portion of the solid-liquid interface in the growing of the silicon single crystal.

The control of the step difference of the solid-liquid interface may be applied to a late stage of the growth of the shoulder in the growing of the silicon single crystal.

The pressure may be in the range of 100 to 10000 torr during the silicon single crystal growth.

A radial resistivity gradient (RRG) of the silicon single crystal may be in the range of 1 to 15% in the growing of the silicon single crystal.

Resistivity may increase in the solid-liquid interface of the silicon single crystal, and the increase of resistivity may be controlled to allow temperature difference causing resistivity increase to exhibit at intervals of about 10 to about 15% on average in the growing of the silicon single crystal.

The control of the resistivity increase may be applied to the growth of the shoulder in the growing of the silicon single crystal.

A growth rate of the silicon single crystal at an initial stage of growth of the body may have a negative gradient in the growing of the silicon single crystal.

The initial stage of the growth of the body may correspond to a solidification rate of 25% or less, and the growth rate of the silicon single crystal may be reduced to 0.1 to 0.3 mm/min.

The growth rate of the silicon single crystal may have a negative gradient and a positive gradient during the growth of the body. The negative gradient may vary within 10 to 20%, and the positive gradient may vary within 5 to 10% in the growth of the silicon single crystal.

The ranges of variation of the negative and positive gradients may be applied to a point when the gradient of the growth rate of the silicon single crystal is changed from negative to positive.

### Advantageous Effects

According to the present invention, a method of growing a silicon single crystal using a low-melting point volatile dopant is provided. According to the method, manufacturing costs may be reduced by reducing the amount of the relatively expensive dopant material by minimizing the amount of the dopant required to obtain desired resistivity and by reducing the amount of the dopant volatilizing by increasing pressure after doping.

In addition, contamination caused by volatilization of the dopant may be efficiently prevented, and the yield of the silicon single crystal may be increased by adjusting the content of inert gas in addition to increasing the pressure.

Furthermore, the yield of the silicon single crystal may be increased by reducing the amount of the dopant volatilizing by controlling the content of inert gas when the volatilization rate of the dopant is accelerated due to decrease in the amount of the silicon melt.

### DESCRIPTION OF DRAWINGS

FIG. 1 is a graph illustrating incidence of polycrystallization according to stages of a growth process of a silicon single crystal;

FIGS. 2A and 2B are graphs illustrating frequencies of polycrystallization according to stages of a growth process of a silicon single crystal;

FIG. 3 is a table illustrating yield with respect to a ratio of inert gas quantity to pressure of a chamber;

FIGS. 4A to 4D are diagrams illustrating phase transformation according to the degree of constitutional supercooling;

FIGS. 5A to 5D illustrate shapes of a solid-liquid interface in accordance with increase in solid solubility;

FIG. 6 is a graph illustrating resistivity according to the solid-liquid interface and constitutional supercooling;

FIGS. 7A and 7B are graphs illustrating phase change according to melting point;

FIG. 8 is a graph illustrating temperature rise rate with respect to the number of crucible rotation;

FIGS. 9A to 9D are diagrams illustrating crystallization according to constitutional supercooling;

FIG. 10 is a graph illustrating resistivity with respect to growth of a silicon single crystal;

FIG. 11 is a diagram illustrating resistivity variation with respect to a horizontal growth length of a shoulder;

FIG. 12 illustrates a relationship between growth rate and resistivity; and

FIG. 13 is a graph illustrating the slope of the growth rate with respect to resistivity.

### BEST MODE

Reference will now be made in detail to the exemplary embodiments of the present invention, examples of which are illustrated in the accompanying drawings.

It will be understood that, when an element such as a layer (film), region, pattern or structure is referred to as being formed “on” or “under” another element, such as a substrate, layer (film), region, pad or pattern, it can be directly “on” or “under” the other element or be indirectly formed with intervening elements therebetween. It will also be understood that “on” or “under” the element may be described relative to the drawings.

In the drawings, the thickness or size of each layer may be exaggerated, omitted or schematically illustrated for clarity and convenience. In addition, the size of each constituent element does not wholly reflect an actual size thereof.

According to the present invention, a silicon melt is prepared in a crucible of an apparatus for growing a silicon single crystal, and then a low-melting point dopant is added to the silicon melt.

Then, a silicon single crystal is pulled up from the silicon melt to which the dopant is added in the order of a neck, a shoulder, and a body.

In this regard, the silicon single crystal growth may include a necking process for growing a thin and long crystal from a seed crystal, a shouldering process for growing the crystal in a radial direction to a target diameter, and a body growth process for growing the crystal having a predetermined diameter.

Then, the diameter of the crystal is gradually decreased after the body growing up to a predetermined length, and the silicon single crystal growth is completed through a tailing process to separate the crystal from the silicon melt.

As such, according to the present invention, when a high purity silicon single crystal is grown using a volatile low-melting point dopant, a solid-liquid interface may be precisely controlled to increase silicon single crystal yield and improve productivity. As a result, a silicon single crystal having low resistivity may be obtained through reduction of a supercooled region.

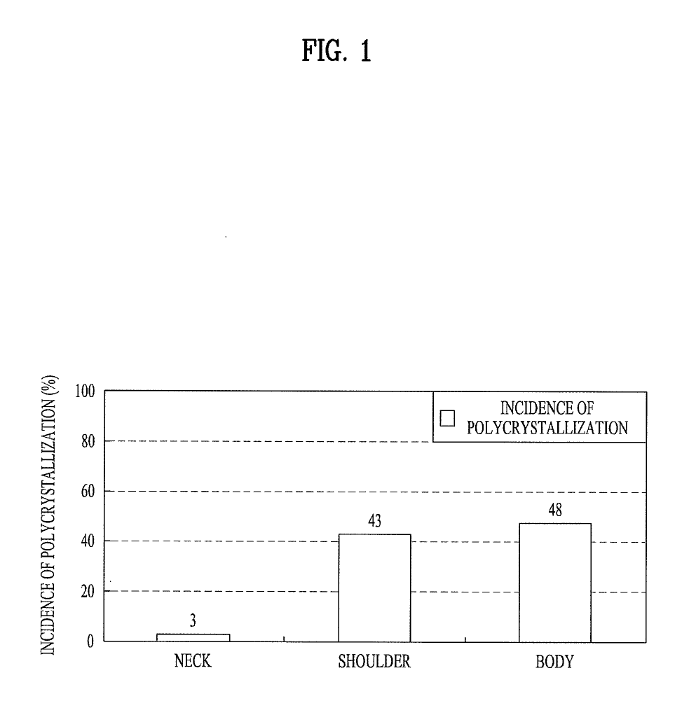

FIG. 1 is a graph illustrating incidence of polycrystallization according to stages of a growth process of a silicon single crystal.

As shown in FIG. 1, the body growth process of the silicon single crystal exhibits the highest incidence of polycrystallization, and the necking process of the silicon single crystal exhibits the lowest incidence of polycrystallization. The incidence of polycrystallization of the shouldering process is within a range between those of the body growth process and the necking process.

In the growth of a high purity silicon single crystal ingot, the silicon single crystal ingot has a region, a temperature of which is lower than that of the silicon melt. When a temperature gradient of the ingot increases, crystallization occurs in the solidifying silicon ingot from a region having a lower temperature than that of the solid-liquid interface. In this regard, polycrystallization may occur due to crystal lattice misalignment.

Thus, as the concentration of the low-melting point dopant contained in the silicon melt increases, the condition becomes similar to that of constitutional supercooling. Since a solid phase tends to be formed under the solid-liquid interface, polycrystallization may easily occur due to difference of cooling driving force in accordance with phase transformation.

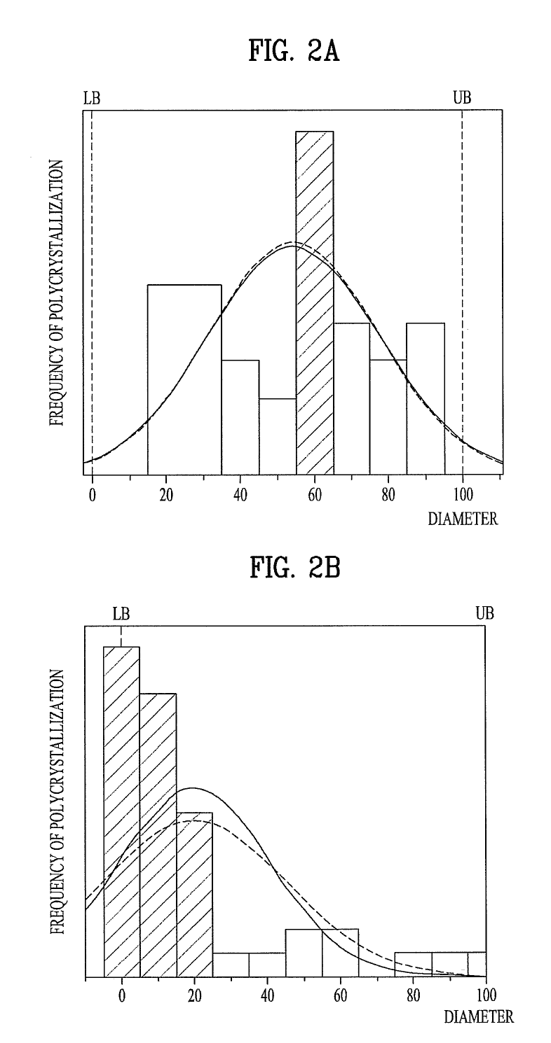

FIGS. 2A and 2B are graphs illustrating frequencies of polycrystallization according to stages of a growth process of a silicon single crystal. FIG. 2A shows frequency of polycrystallization during the shouldering process, and FIG. 2B shows frequency of polycrystallization during the body growth process.

As illustrated in FIG. 2A, polycrystallization frequently occurs at about 60% of the total diameter in the shouldering process. As illustrated in FIG. 2B, polycrystallization frequently occurs at about 25% of the total length in the body growth process based on the solidification rate.

In the silicon single crystal growth, resistivity increases and then decreases at a transition portion from the shoulder to the body. In general, as the silicon single crystal becomes longer, the resistivity thereof decreases.

However, when the solid-liquid interface has a concave shape, phase transformation to the solid phase occurs last at the central region of the solid-liquid interface. Accordingly, diffusion spreads from the central region along the solid-liquid interface, so that resistivity decreases and then increases.

As such, the shoulder has a concave solid-liquid interface since the amount of heat received from the silicon melt is greater than the amount of heat discharged from the shoulder.

Even when the growth rate increases, it is difficult to change the solid-liquid interface due to a large volumetric difference.

In addition, when the solid-liquid interface has a concave shape, it is relatively difficult to grow the silicon single crystal. However, it is possible to grow the crystal at the shoulder since a temperature gradient between the silicon melt and the shoulder is relatively low.

According to the present invention, a step difference between the center of the solid-liquid interface and an imaginary line formed with at least two end points of the solid-liquid interface should be less than about 20% before entering the body growth process.

Due to increase in constitutional supercooling, a solid phase is easily formed at edge portions of the solid-liquid interface to accelerate polycrystallization as the solid-liquid interface becomes lower.

Furthermore, heat transfer is more efficiently performed at edge portions compared to the central region. Thus, when the center of the solid-liquid interface is higher than the end portions thereof by about 20% or more, latent heat of solidification increases to reduce the supercooled region thereunder. Thus, the growth of the silicon single crystal may be inhibited.

In order to prevent polycrystallization due to constitutional supercooling, a maximum height of the solid-liquid interface needs to be controlled within about 20% based on end portions thereof. The variation needs to be within about 10%. Preferably, the center may be formed at the same level to the end portions of the solid-liquid interface.

In other words, in the late stage of the shouldering process of silicon single crystal growth, the solid-liquid interface of the silicon single crystal may be controlled such that a step difference between the center of the solid-liquid interface and end portions of the solid-liquid interface is less than about 20%.

In addition, since the silicon single crystal growing in the shoulder has a relatively small volume, influence on the supercooled region in accordance with temperature increase is less than that of the body, even when the cooling effect is maximized to form a concave solid-liquid interface.

Thus, even when the solid-liquid interface has a concave shape, the condition becomes less similar to that of the constitutional supercooling at a specific concentration or more.

When a low-melting point dopant is used, the dopant volatilizes from the surface of the silicon melt (heat of vaporization), increasing the surface temperature thereof. In particular, the solid-liquid interface has a great influence on the shoulder due to a small volume available for heat transfer.

Such effect may cause increase in solidification temperature.

Accordingly, when the shoulder is supercooled at a conventional temperature, the temperature is not sufficient for maintaining the supercooled region in the shoulder, thereby inducing polycrystallization.

In order to prevent dislocation of the shoulder, the heat of solidification needs to be further reduced to form a sufficient supercooled region.

Particularly, since the shoulder vertically and horizontally grows, insufficient supercooling temperature with respect to the increased solidification temperature needs to be secured.

During horizontal growth, surface temperature decrease is faster than maintaining of the supercooled region. Accordingly, it is important to control temperature at about 40% or less of the shouldering process in which vertical growth is dominant.

The sufficient supercooled region may be confirmed by using three methods: a first method of measuring uniformity of a facet surface, a second method of measuring an angle of the facet surface, and a third method of measuring a diameter of the shoulder and time period before entering main horizontal growth.

According to the first and second methods, the facet surface may be formed to have a uniform shape although the uniformity and angle may vary in accordance with crystal growth orientation.

In order to implement this, the length of the neck should be kept at a predetermined level and an amount of inert gas capable of reducing volatility in terms of heat of vaporization and efficiently removing contaminants is an important factor.

In addition, according to the third method, since a start point of horizontal growth varies according to the location where the facet surface grows with regard to the total growth diameter, there is a need to clarify this. Here, the time therefor is used to measure temperature required to maintain a supercooled region.

Thus, during silicon single crystal growth according to the present invention, the length of the neck may be controlled within the range of about 35 to about 45 cm during the shouldering process, and a ratio of inert gas quantity to pressure of a chamber may be controlled to about 1.5 or less.

In this regard, the ratio of inert gas quantity to pressure of a chamber may be controlled from the shouldering process in the silicon single crystal growth.

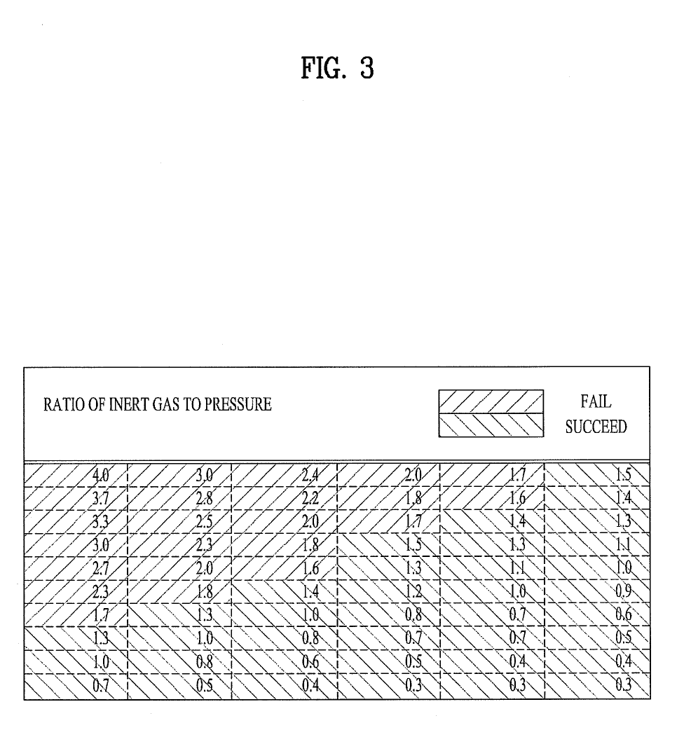

FIG. 3 is a table illustrating yield with respect to a ratio of inert gas quantity to pressure of a chamber. As illustrated in FIG. 3, when the ratio of inert gas quantity to pressure of a chamber is controlled to be about 1.5 or less, it is confirmed that productivity of the silicon single crystal grown using a highly volatile dopant is improved.

When the ratio of inert gas quantity to pressure of a chamber is greater than about 1.5, the shape of the facet varies, thereby becoming non-uniform.

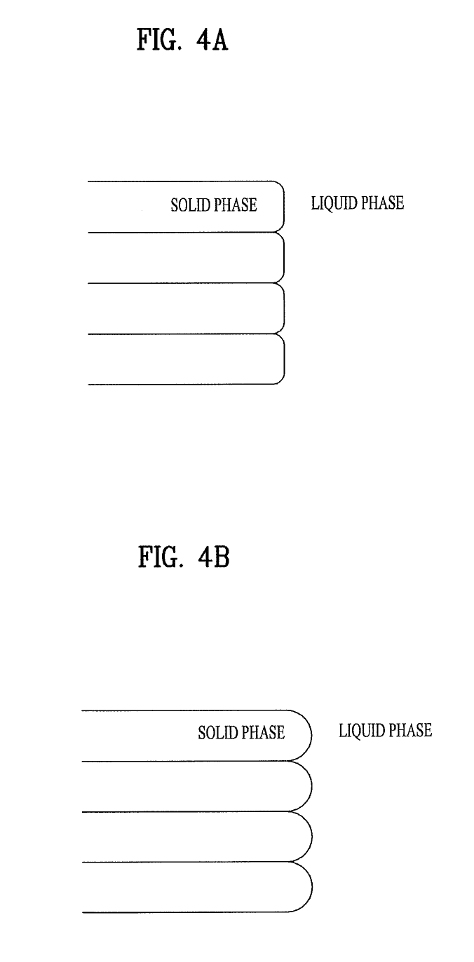

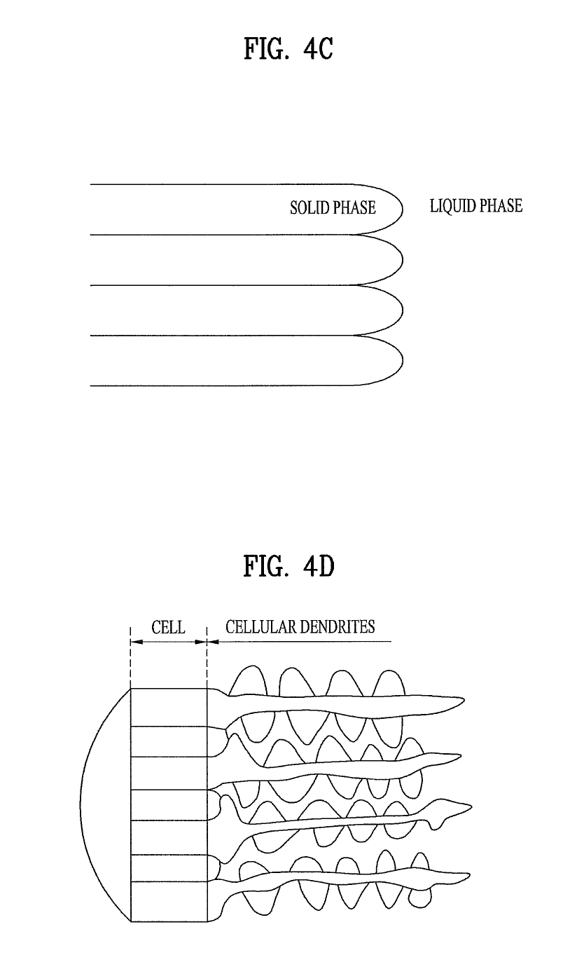

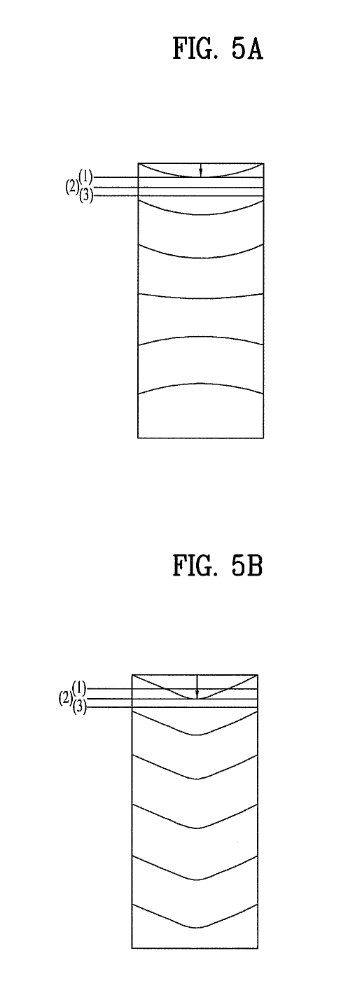

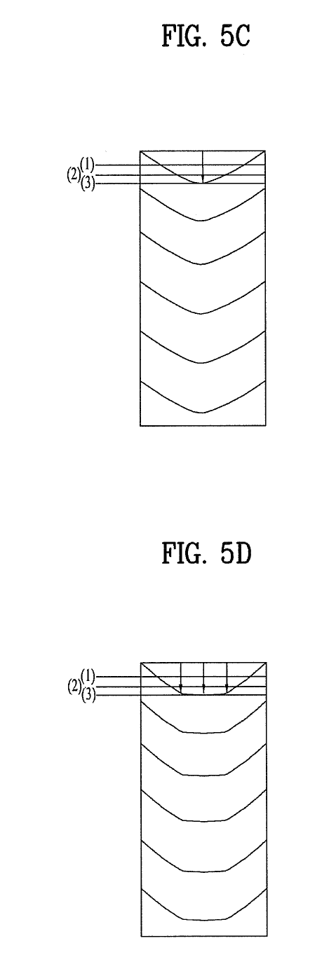

FIGS. 4A to 4D are diagrams illustrating phase transformation according to the degree of constitutional supercooling. FIGS. 5A to 5D illustrate shapes of a solid-liquid interface in accordance with increase in solid solubility.

When arsenic (As) is used, as the amount of solid solution increases, temperature may rapidly decrease during phase transformation from a liquid phase to a solid phase.

As illustrated in FIGS. 4A to 4D, when constitutional supercooling does not occur, the silicon single crystal grows such that the solid-liquid interface has a planar shape. When constitutional supercooling occurs, a cellular interface is formed. As supercooling is further increased, cellular dendrites grow downward.

In addition, as illustrated in FIGS. 5A to 5D, as solid solubility increases in silicon, the interface is lowered to be a more pointed form.

In this regard, when the interface has a pointed shape, an area increases the vicinity of a candidate region where the constitutional supercooling occurs. As supercooling proceeds, a relatively supercooled region is formed at a higher temperature than the temperature of the solid-liquid interface under the solid-liquid interface, so that amorphous crystals growth may occur.

In addition, as this portion reaches a temperature range over the solid-liquid interface according to the crystal growth rate, amorphous crystals and a liquid phase are simultaneously phase-transformed to a solid phase. Thus, solidification occurs under thermal stress.

In this case, scratches may be found on the surface of the silicon single crystal.

In addition, as the amount of a solute added to a solvent increases, phase transformation temperature from a liquid phase of the solvent and the solute into a solid phase rapidly decreases. Particularly, a sharp gradient is formed at a portion where the solid solution limitation occurs.

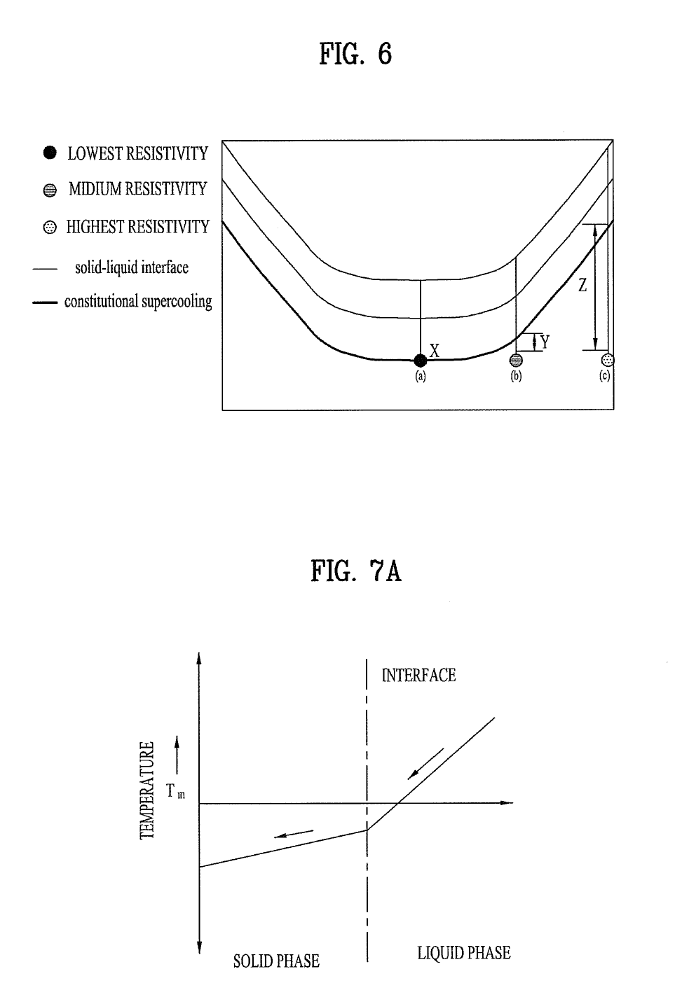

FIG. 6 is a graph illustrating resistivity according to the solid-liquid interface and constitutional supercooling.

As illustrated in FIG. 6, when the solid-liquid interface has a planar shape, temperature difference between a cushion region and the solid-liquid interface decreases.

In comparison of Y and Z with X, when the solid-liquid interface has a concave shape, the cushion region may be expanded, increasing the risk of dislocation.

When growth rate is controlled by constitutional supercooling, latent heat of solidification generally consumes most of thermal energy through crystal during high-speed growth.

However, as the growth rate decreases, latent heat of solidification is transferred to both of the crystal (solid phase) and the liquid phase.

The cushion region expands as the amount of the solute contained in the solvent increases. Here, the growth rate is reduced in order to reduce a temperature gradient between the solid-liquid interface and the cushion region.

That is, when the temperature of the solid-liquid interface is about 1300° C., the temperature range where the cushion region is formed increases as the concentration increases.

Since crystallization occurs at a temperature higher than the temperature of the solid-liquid interface, the crystal grows before a sufficient supercooled region is formed. Thus, a single crystal may not be obtained.

According to the present invention, the interface should have a planar shape to minimize solidification difference between the solid-liquid interface and the constitutional supercooled region although there is a slight temperature difference.

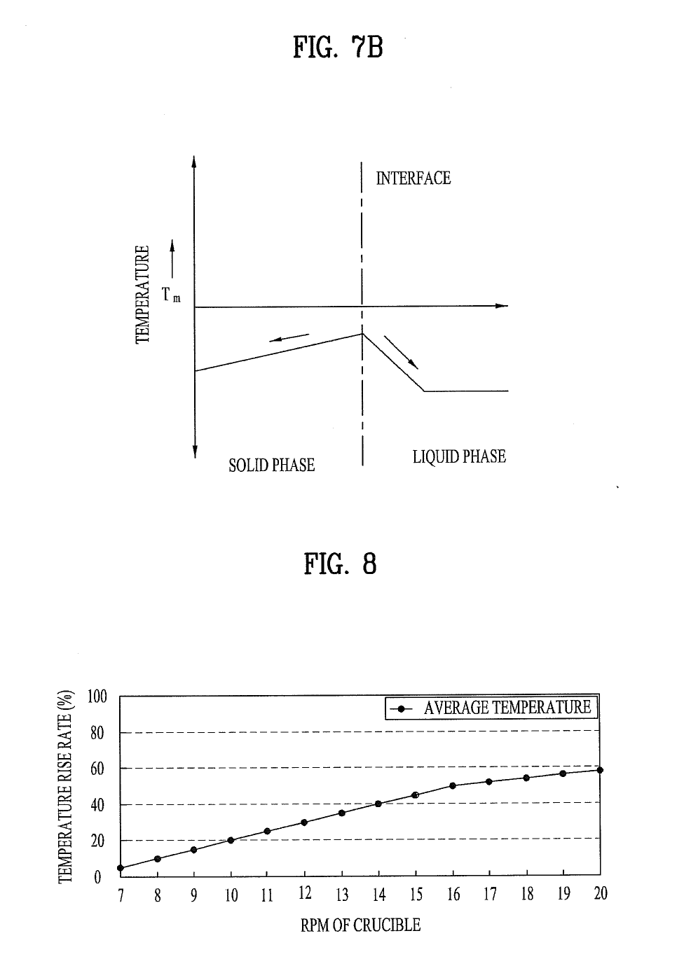

FIGS. 7A and 7B are graphs illustrating phase change according to melting point.

As illustrated in FIGS. 7A and 7B, a silicon single crystal is formed by the constitutional supercooling at a temperature higher than that of the solid-liquid interface.

Thus, in order to reduce the effects of constitutional supercooling, the temperature gradient between the solid-liquid interface and the supercooled region needs to be minimized.

This is because, as the temperature gradient increases, the solid-liquid interface becomes more concave.

FIG. 8 is a graph illustrating temperature rise rate with respect to rpm of the crucible. The crucible is rotated to reduce the temperature gradient between the solid-liquid interface and the supercooled region.

As illustrated in FIG. 8, as the rpm of the crucible increases, convection of the silicon melt is more activated. Thus, heating power of the apparatus for growing the silicon single crystal increases, resulting in a proportionally increase in temperature.

The increase in overall temperature may have an effect of reducing the amount of the solid added to the solvent, thereby reducing the effect of the constitutional supercooling.

However, since increase in the temperature rise rate of the rpm of the crucible is limited, the temperature may be maintained within a proper range.

According to the present invention, the temperature gradient between the solid-liquid interface and the supercooled region may be minimized at about 12 to 16 rpm. Accordingly, the interface may be prevented from becoming concave.

In addition, rotation of the upper single crystal may also yield the same effect as rotation of the lower crucible.

In other words, during growth of the silicon single crystal according to the present invention, the rate of rotation of the silicon single crystal may be controlled within the range of about 12 to 16 rpm during the shouldering process. If desired, the rate of rotation of the crucible containing the silicon melt may be controlled within the range of about 12 to 16 rpm.

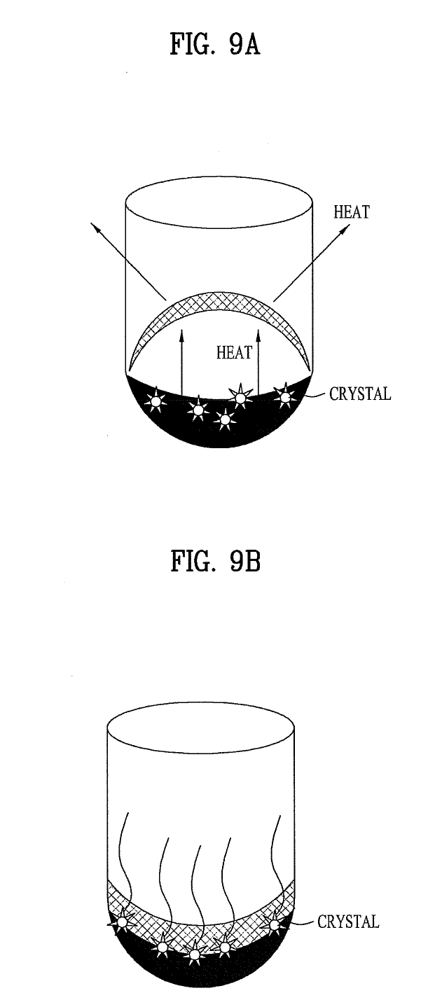

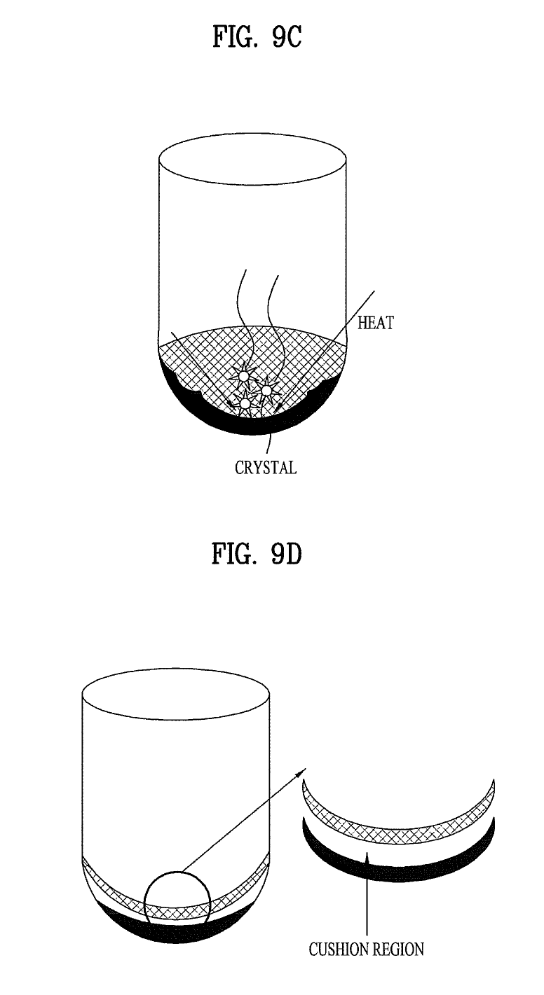

FIGS. 9A to 9D are diagrams illustrating crystallization according to constitutional supercooling.

FIG. 9A illustrates that crystals are formed at a region further supercooled than temperature of the constitutional supercooling. FIG. 9B illustrates that crystals are formed by additional supercooling as surface area increases during nucleation of the solid-liquid interface.

In FIG. 9C, a constitutional supercooled region is formed within the solid-liquid interface and crystallization occurs in this region. As concentration increases, the more supercooled region is reduced by the solid-liquid interface. Thus, dislocation occurs at the center of the single crystal.

Referring to FIG. 9D, as the growth rate is controlled such that the solid-liquid interface is disposed apart from the constitutional supercooled region by a predetermined distance, variation caused by temperature may be reduced.

As such, as concentration increases, the constitutional supercooled region may expand.

When the growth rate of the silicon single crystal is increased by increasing the rpm of the crucible to about 16 rpm or more when a constitutional supercooled region is present, latent heat of solidification is transferred toward the silicon melt to reduce the supercooled region of the solid-liquid interface.

Particularly, as the temperature gradient between the constitutional supercooled region and the solid-liquid interface increases, and as a temperature range for crystallization expands, crystallization of the constitutional supercooled region is further accelerated.

Furthermore, when the growth rate of the silicon single crystal is reduced by decreasing the rpm of the crucible to about 12 rpm or less, the solid-liquid interface is located at a lower portion than the constitutional supercooled region.

That is, when the constitutional supercooled region, which has a sufficiently lower temperature than the solid-liquid interface, contacts the edge of the solid-liquid interface or is contained in the solid-liquid interface, polycrystallization may occur due to lattice mismatch.

Thus, the growth rate of the silicon single crystal may be controlled to have suitable resistivity by adjusting the rpm of the crucible in the range of about 12 to about 16 rpm.

Since a low-melting point dopant is generally highly volatile, the center of the single crystal has the lowest resistivity. Accordingly, polycrystallization occurs at the center due to constitutional supercooling, thereby causing dislocation.

In order to reduce dislocation caused by the constitutional supercooling, resistivity variation in a radial direction may be less than about 15%, preferably less than about 10%.

To this end, the temperature gradient between the solid-liquid interface and the constitutional supercooled region in a radial direction needs to be reduced.

As the overall temperature increases, thermal energy of the low-melting point dopant added to the single crystal is reduced in a cushion-like manner, thereby preventing dislocation caused by thermal stress.

According to the present invention, the rpm of the crucible may be controlled within the range of about 12 to about 16 rpm.

Additionally, in order to reduce constitutional supercooling according to resistivity variation as well as to control of the interface, volatilization rate needs to be controlled.

Thus, according to the present invention, difference of constitutional supercooling caused by resistivity variation may be minimized by controlling the ratio of inert gas quantity to pressure of a chamber to 1.5 or less and adjusting the pressure to about 100 torr or more.

If desired, the pressure may be in the range of about 100 to about 10,000 torr.

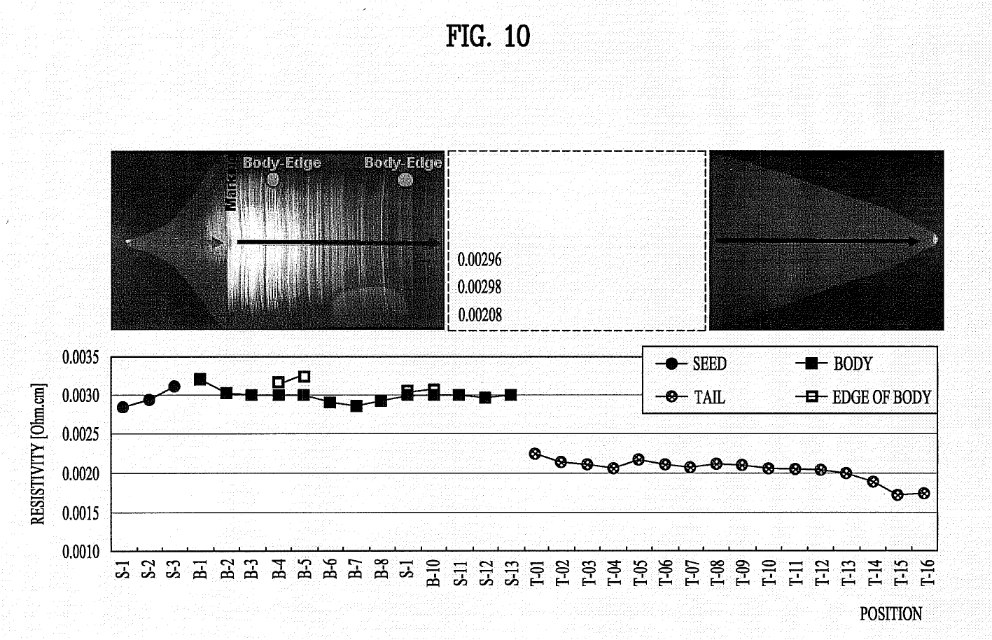

FIG. 10 is a graph illustrating resistivity with respect to growth of a silicon single crystal using a low-melting point dopant.

Resistivity of the shoulder increases with time since volatilization rate varies due to temperature variation in accordance with position.

Since the silicon melt is maintained by applying heat from an external heat source in silicon single crystal growth, the center of the silicon melt has a lower temperature than any other position.

From a top view of the solid-liquid interface, temperature is distributed in concentric circles. The volatilization amount at each temperature may be determined by measuring resistivity change with respect to the diameter of the growing shoulder.

Particularly, when the solid-liquid interface has a concave shape curved toward the silicon melt, diffusion occurs from the center of the shoulder with a higher concentration to edges of the shoulder with a lower concentration. Accordingly, the concentration of the center increases according to the length of the silicon single crystal or time.

As illustrated in FIG. 10, when the solid-liquid interface has a concave shape, resistivity increases at the center. When the solid-liquid interface has a planar shape, resistivity remains constant.

Due to such effect, when the solid-liquid interface has a concave shape, variation of radial resistivity gradient (RRG) decreases. As the solid-liquid interface becomes more convex, RRG increases.

Furthermore, increase of RRG may be controlled by about 15% or less.

As such, RRG of the silicon single crystal may be in the range of about 1 to about 15%.

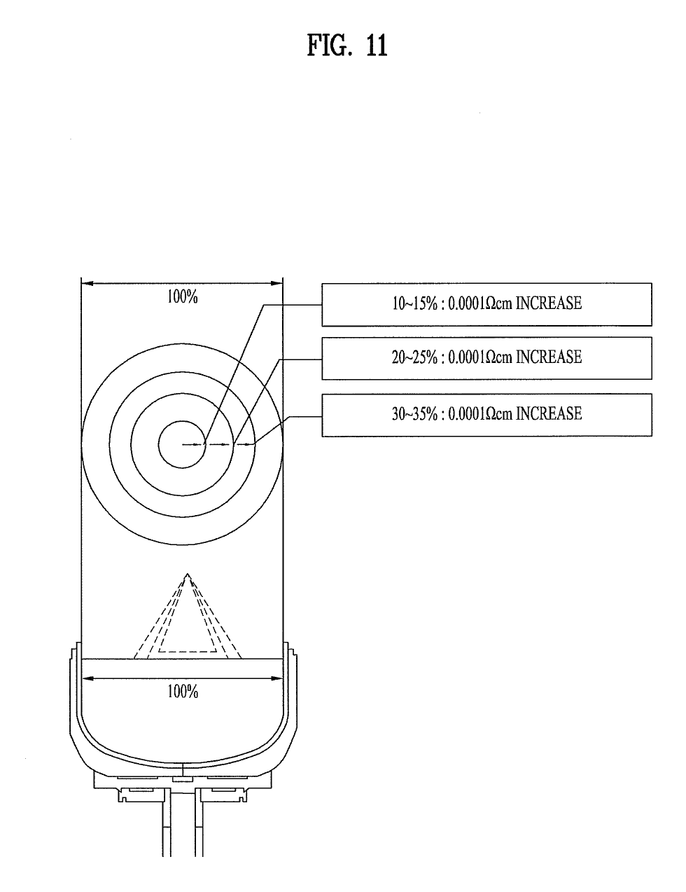

FIG. 11 is a diagram illustrating resistivity variation with respect to the horizontal growth length of the shoulder.

As illustrated in FIG. 11, the volatilization rate varies according to temperature difference with respect to the position in the silicon melt. Accordingly, resistivity may reversely increase.

Particularly, when the solid-liquid interface has a concave shape, resistivity of the center increases as concentration varies by diffusion.

As illustrated in FIG. 11, temperature difference causing resistivity increase is exhibited at intervals of about 10 to about 15% on average.

For the control as described above, the rpm of the crucible needs to be controlled within the range of about 12 to about 16 rpm according to the present invention. Growth of a high-purity silicon single crystal needs to be performed by minimizing temperature.

As such, during the shouldering process of the silicon single crystal growth process according to the present invention, resistivity of the solid-liquid interface increases in the silicon single crystal. Preferably, the increase in resistivity may be controlled such that the temperature difference is exhibited at intervals of about 10 to about 15% on average.

In addition, in order to reduce dislocation caused by constitutional supercooling, the growth rate and resistivity may be optimized.

Particularly, the solid-liquid interface needs to be uniformly maintained at the initial stage of the body growth process where the solid-liquid interface rapidly changes, e.g., at a solidification rate of 25% or less, to reduce dislocation caused by constitutional supercooling.

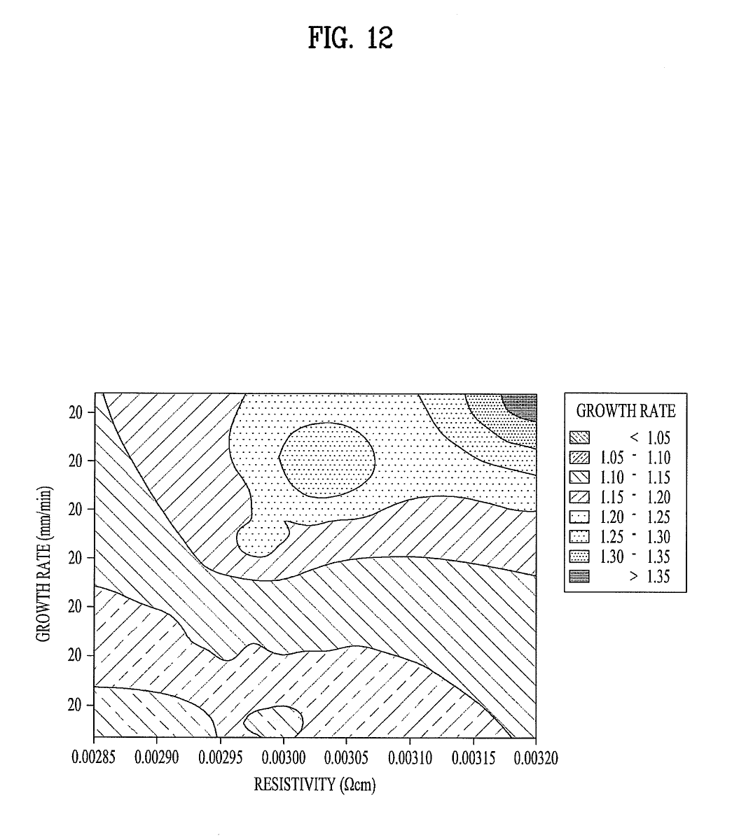

FIG. 12 illustrates the relationship between growth rate and resistivity.

As illustrated in FIG. 12, the solid-liquid interface rapidly changes at a solidification rate of 25% or less, the gradient of the growth rate needs to be increased.

Based on these results, the gradient of the growth rate needs to be reduced to about 0.1 to about 0.3 mm/min. As resistivity decreases, the gradient increases.

During silicon single crystal growth according to the present invention, the growth rate of the silicon single crystal may have a negative gradient at the initial stage of the body growth process. The initial stage of the body growth process may be defined as a solidification rate of 25% or less. The growth rate of the silicon single crystal may be controlled within the range of about 0.1 to 0.3 mm/min.

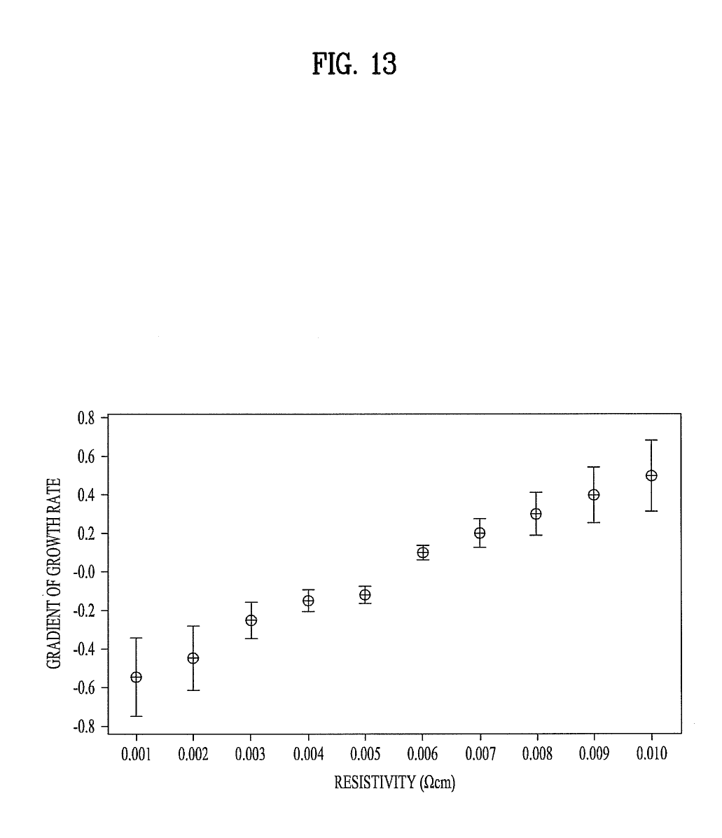

FIG. 13 is a graph illustrating the gradient of the growth rate with respect to resistivity, i.e., the growth rate according to resistivity at a solidification rate of 25% or less.

As illustrated in FIG. 13, as resistivity decreases, the growth rate has a negative gradient. On the other hand, as resistivity increases, the growth rate has a positive gradient.

When the growth rate is within the range described above, the solid-liquid interface may have a planar shape.

That is, at a resistivity of about 0.005 or greater, the silicon single crystal may grow although the slope of the growth rate is not within the range described above. However, the yield thereof may slightly decrease.

Particularly, when the growth rate has a positive gradient, the silicon single crystal may grow even after change of the gradient from positive to negative.

However, when the growth rate has a negative gradient, the silicon single crystal does not grow after change of the gradient from negative to positive.

Thus, a narrow range of this gradient indicates a point where the positive and negative gradients meet. The negative gradient varies within about 10 to 20%, and the positive gradient varies within about 5 to 10%.

As described above, during the body growth process of the silicon single crystal growth process according to the present invention, the growth rate of the silicon single crystal may have a negative gradient and a positive gradient. The negative gradient may vary within about 10 to 20%, and the positive gradient may vary within about 5 to 10%.

In this regard, the ranges of variation of the negative and positive gradients may be applied to a point when the gradient of the growth rate of the silicon single crystal is changed from negative to positive.

Thus, according to the method, manufacturing costs may be reduced by reducing the amount of the relatively expensive dopant material by minimizing the amount of the dopant to obtain desired resistivity and by reducing the amount of the dopant volatilizing by increasing pressure after doping.

In addition, contamination caused by volatilization of the dopant may be efficiently prevented, and the yield of the silicon single crystal may be increased by adjusting the content of inert gas in addition to increasing the pressure.

Furthermore, the yield of the silicon single crystal may be increased by reducing the amount of the dopant volatilizing by controlling the content of inert gas when the volatilization rate of the dopant is accelerated due to decrease in the amount of the silicon melt.

The features, structures and effects and the like described in the embodiments are included in at least one embodiment of the present invention and are not necessarily limited to one embodiment. Furthermore, the features, structures, effects and the like provided in each embodiment can be combined or modified in other embodiments by those skilled in the art to which the embodiments belong. Therefore, contents related to the combination and modification should be construed to be included in the scope of the present invention.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

1. A method of growing a silicon single crystal, the method comprising:
preparing a silicon melt;
adding a dopant having a lower melting point than the silicon melt to the silicon melt; and
growing a silicon single crystal from the silicon melt to which the dopant is added in the order of a neck, a shoulder, and a body,
wherein a length of the neck is adjusted to 35 to 45 cm, and a ratio of inert gas quantity to pressure of a chamber is adjusted to 1.5 or less in the growing of the silicon single crystal.

2. The method according to claim 1, wherein the adjusting of the ratio of inert gas quantity to pressure of a chamber is applied to from growth of the shoulder in the growing of the silicon single crystal.

3. The method according to claim 1, wherein a rotation rate of the silicon single crystal is in the range of 12 to 16 rpm in the growing of the silicon single crystal.

4. The method according to claim 1, wherein a rotation rate of a crucible containing the silicon melt is in the range of 12 to 16 rpm in the growing of the silicon single crystal.

5. The method according to claim 1, wherein a solid-liquid interface of the silicon single crystal is controlled to have a step difference of 20% or less between the center of the solid-liquid interface and an edge portion of the solid-liquid interface in the growing of the silicon single crystal.

6. The method according to claim 5, wherein the control of the step difference of the solid-liquid interface is applied to a late stage of the growth of the shoulder in the growing of the silicon single crystal.

7. The method according to claim 1, wherein a radial resistivity gradient (RRG) of the silicon single crystal is in the range of 1 to 15% in the growing of the silicon single crystal.

8. The method according to claim 1, wherein resistivity increases in the solid-liquid interface of the silicon single crystal, and the increase of resistivity is controlled to allow temperature difference causing resistivity increase to exhibit at intervals of about 10 to about 15% on average in the growing of the silicon single crystal.

9. The method according to claim 8, wherein the control of the resistivity increase is applied to the growth of the shoulder in the growing of the silicon single crystal.

10. The method according to claim 1, wherein a growth rate of the silicon single crystal at an initial stage of growth of the body has a negative gradient in the growing of the silicon single crystal.

11. The method according to claim 10, wherein the initial stage of the growth of the body corresponds to a solidification rate of 25% or less.

12. The method according to claim 10, wherein the growth rate of the silicon single crystal is reduced to 0.1 to 0.3 mm/min.

13. The method according to claim 1, wherein the growth rate of the silicon single crystal has a negative gradient and a positive gradient during the growth of the body, wherein the negative gradient varies within 10 to 20%, and the positive gradient varies within 5 to 10% in the growth of the silicon single crystal.

14. The method according to claim 13, wherein the ranges of variation of the negative and positive gradients are applied to a point when the gradient of the growth rate of the silicon single crystal is changed from negative to positive.
